(19) United States
(12) Patent Application Publication
(10) Pub. No.: US 2026/0082966 A1
(43) Pub. Date: Mar. 19, 2026

(54) UNIFORM SEED LAYER FOR THROUGH HOLES IN GLASS SUBSTRATES

(71) Applicant: Intel Corporation, Santa Clara, CA (US)

(72) Inventors: Lei JIN, Chandler, AZ (US); Suresh Tanaji NARUTE, Chandler, AZ (US); Ali LEHAF, Phoenix, AZ (US); Steve S. CHO, Chandler, AZ (US); Jacob VEHONSKY, Chandler, AZ (US); Srinivas Venkata Ramanuja PIETAMBARAM, Chandler, AZ (US)

(21) Appl. No.: 18/886,647

(22) Filed: Sep. 16, 2024

(51) Int. Cl. H01L 23/498; H01L 21/48; H01L 23/15

(52) U.S. Cl. CPC H10W 70/685; H10W 70/095; H10W 70/65; H10W 70/664; H10W 70/69; H10W 70/692

(57) ABSTRACT

Embodiments disclosed herein include an apparatus that comprises a substrate, and the substrate includes glass. In an embodiment, an opening is provided through a thickness of the substrate, and a layer is along a sidewall of the opening. In an embodiment, the layer comprises a polymer and an electrical conductor that comprises carbon. In an embodiment, a via is provided in the opening, and the via is an electrically conductive material.

### BACKGROUND

Electronics packaging substrates typically include a core. Existing core materials include organic dielectrics that may comprise fiber reinforcement materials. As devices continue to scale in complexity, alternative core materials are desired. For example, package cores that include solid glass layers may be one potential option. Glass cores enables stiffer substrates, flatter surfaces, and can improve electrical performance.

In the case of power delivery applications, thick glass core substrates may be used. However, it is challenging to form voidless vias in high aspect ratio openings through the glass core. For example, electroless plating processes that are typically used to form seed layers on the glass may not plate uniformly through the entire thickness of the opening. Other solutions, such as atomic layer deposition (ALD) processes for depositing the seed layer are expensive and not compatible with existing electronics package substrate manufacturing process flows.

### BRIEF DESCRIPTION OF THE DRAWINGS

FIG. 1 is a cross-sectional illustration of a glass core with a via that includes a void, in accordance with an embodiment.

FIGS. 2A-2C are cross-sectional illustrations depicting a process for plating a via through a glass core with a hybrid seed layer that includes a polymer and an electrically conductive carbon layer, in accordance with an embodiment.

FIG. 3A is a cross-sectional illustration of a glass core with a via plated up from a plurality of hybrid seed layers, in accordance with an embodiment.

FIG. 3B is a cross-sectional illustration of a glass core with a via plated up from a hybrid seed layer with a copper liner, in accordance with an embodiment.

FIG. 3C is a cross-sectional illustration of a glass core with a via plated up from a plurality of hybrid seed layers with an overlying copper liner, in accordance with an embodiment.

FIG. 4A is a cross-sectional illustration of a package substrate with a glass core that comprises vias that are plated up from a hybrid seed layer that includes a polymer and an electrically conductive carbon layer, in accordance with an embodiment.

FIG. 4B is a cross-sectional illustration of a package substrate with a glass core that comprises vias that are plated up from a hybrid seed layer and a copper liner, in accordance with an embodiment.

FIGS. 5A-5F are cross-sectional illustrations that depict a process for forming a package substrate with a glass core that includes vias that are plated up from a hybrid seed layer that includes a polymer and an electrically conductive carbon layer, in accordance with an embodiment.

FIG. 6 is a flow diagram that depicts a process for forming a package substrate with a glass core that includes vias that are plated up from a hybrid seed layer, in accordance with an embodiment.

FIG. 7 is a cross-sectional illustration of an electronic system that comprises a package substrate with a glass core that includes vias that are plated from hybrid seed layers that comprise a polymer and an electrically conductive carbon layer, in accordance with an embodiment.

FIG. 8 is a schematic of a computing device built in accordance with an embodiment.

### EMBODIMENTS OF THE PRESENT DISCLOSURE

Described herein are package architectures with glass substrates that include vias that are plated from seed layers that comprise a polymer and carbon, in accordance with various embodiments. In the following description, various aspects of the illustrative implementations will be described using terms commonly employed by those skilled in the art to convey the substance of their work to others skilled in the art. However, it will be apparent to those skilled in the art that the present disclosure may be practiced with only some of the described aspects. For purposes of explanation, specific numbers, materials and configurations are set forth in order to provide a thorough understanding of the illustrative implementations. However, it will be apparent to one skilled in the art that the present disclosure may be practiced without the specific details. In other instances, well-known features are omitted or simplified in order not to obscure the illustrative implementations.

Various operations will be described as multiple discrete operations, in turn, in a manner that is most helpful in understanding the present disclosure, however, the order of description should not be construed to imply that these operations are necessarily order dependent. In particular, these operations need not be performed in the order of presentation.

Various embodiments or aspects of the disclosure are described herein. In some implementations, the different embodiments are practiced separately. However, embodiments are not limited to embodiments being practiced in isolation. For example, two or more different embodiments can be combined together in order to be practiced as a single device, process, structure, or the like. The entirety of various embodiments can be combined together in some instances. In other instances, portions of a first embodiment can be combined with portions of one or more different embodiments. For example, a portion of a first embodiment can be combined with a portion of a second embodiment, or a portion of a first embodiment can be combined with a portion of a second embodiment and a portion of a third embodiment.

As noted above, package substrates are moving towards the inclusion of glass based cores in order to provide certain advantages compared to cores that use organic dielectric materials. However, one potential issue with the use of glass cores is finding a process that can be used to form vias through thicknesses of the glass cores. More particularly, existing copper plating processes may not allow cost effective fabrication of high aspect ratio vias in the glass core.

For example, electroless copper deposition processes that are commonly used in organic core panels are not compatible with glass core panels due to the mechanical shocking operation. The mechanical shocking and/or agitation may lead to crack formation and/or other defects within the glass core panel. Atomic layer deposition (ALD) processes may be able to plate sidewalls of openings through the glass cores. Though, such a deposition process is expensive, and the seed layer material commonly used for deposition on glass (e.g., ruthenium) is also expensive.

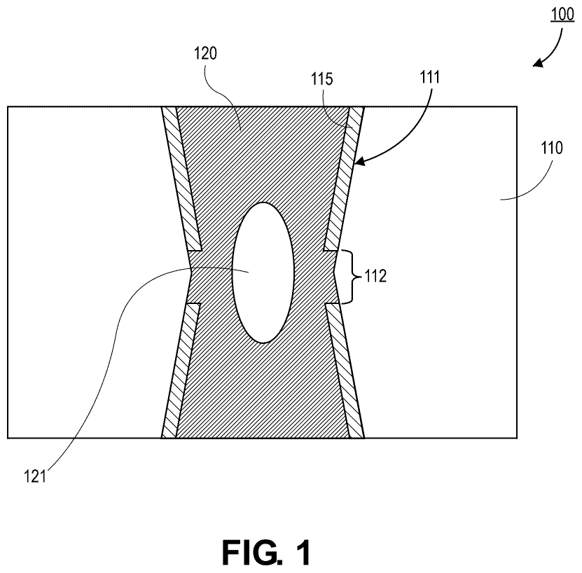

A physical vapor deposition (PVD) process may be used to deposit a seed layer. However, such PVD processes are not effective at forming the seed layer in high aspect ratio openings. This may lead to incomplete seed layer formation along the sidewalls of the opening through the glass core. As such, the plated via may ultimately comprise a void or other defect. An example of such an embodiment is shown in FIG. 1.

Referring now to FIG. 1, a cross-sectional illustration of a portion of a package substrate 100 is shown, in accordance with an embodiment. In an embodiment, the package substrate 100 may comprise a glass core 110. An opening may be formed through a thickness of glass core 110. The opening may have sidewalls 111. In an embodiment, the opening may be filled by a via 120 that is plated up from a seed layer 115 that is provided along the sidewalls 111. However, due to the high aspect ratio of the opening, the plating of the seed layer 115 may not be uniform through the thickness of the glass core 110. For example, the seed layer 115 may be thinner (or completely absent) from a middle region 112 of the opening than the top and bottom of the opening. Due to the different thicknesses of the seed layer 115, the throwing power is not uniform. As such, the middle region 112 of the opening may plate slower than the top and bottom of the opening. This can lead to the formation of a void 121 within the via 120. The presence of a void 121 in the via 120 may negatively impact electrical performance of the package substrate 100 and/or negatively impact the mechanical reliability of the package substrate 100.

Accordingly, embodiments disclosed herein may include the deposition of a hybrid seed layer on the glass core surfaces through the use of electrostatic attraction. For example, the surfaces of the glass core may be charged (e.g., positively charged), and colloids that comprise a polymer and an electrically conductive form of carbon (e.g., graphite, graphene, etc.) are negatively charged. As such, the negatively charged colloids are attracted to the surface of the glass core. The electrostatic attraction also enables uniform deposition without the need for the mechanical shocking or agitation that may result in damage to the glass core. In an embodiment, the hybrid seed layer may be stabilized by cross-linking polymeric portions of the colloid and a conditioner on the surface of the glass core.

In an embodiment, the use of such as hybrid seed layer allows for good (and uniform) throwing power to meet the requirements for seed layer coverage in high aspect ratio via openings in the glass core. Additionally, the process may be implemented with tool sets used in existing process flows. Accordingly, the process is more cost efficient than other plating processes, such as ALD based processes. The use of a hybrid seed layer also provides additional protection to the glass core. For example, the polymer portion of the seed layer may function as a mechanical buffer or liner that can be used to absorb stress within the glass core. As such, crack generation and propagation may be reduced compared to a purely metallic seed layer.

In some embodiments, the via is directly plated up from the hybrid seed layer. In other embodiments, a copper liner (or other electrically conductive material) may be provided over the liner to increase the conductivity over the glass core surface. For example, the copper liner may be applied with a sputtering process or the like. Since the underlying hybrid seed layer provides excellent coverage across the entire glass core surface, the copper liner does not need complete coverage through the entire thickness of the via opening. In yet another embodiment, a hybrid seed layer may be formed to any desired thickness through the use of a cyclical deposition process. Increasing the thickness of the hybrid seed layer may be beneficial for providing a thicker polymeric portion in order to improve the mechanical buffering benefits that protect the glass core.

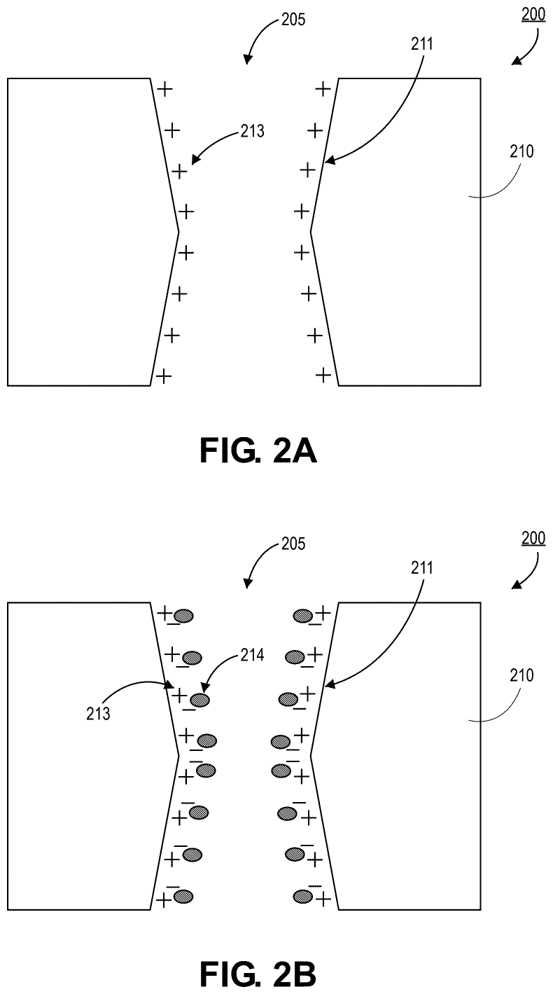

Referring now to FIGS. 2A-2C, a series of cross-sectional illustrations depicting a process for forming a portion of a package substrate 200 with a high aspect ratio via through a glass core is shown, in accordance with an embodiment. In the illustrated embodiments, the deposition of the hybrid seed layer is shown schematically for simplicity and ease of understanding. It is to be appreciated that the colloids would be substantially smaller than the proportions shown in FIGS. 2A-2C.

Referring now to FIG. 2A, a cross-sectional illustration of a portion of the package substrate 200 at a stage of manufacture is shown, in accordance with an embodiment. As shown, the package substrate 200 may comprise a glass substrate 210. In an embodiment, the glass substrate 210 may be part of a glass panel that is used to fabricate a plurality of package substrates 200. The glass substrate 210 may ultimately become a glass core for the package substrate 200 after buildup layers (not shown) are fabricated over and/or under the glass substrate 210.

In an embodiment, the glass substrate 210 may be substantially all glass. The glass substrate 210 may be a solid mass comprising a glass material with an amorphous crystal structure where the solid glass core may also include various structures—such as vias, cavities, channels, or other features—that are filled with one or more other materials (e.g., metals, metal alloys, dielectric materials, etc.). As such, glass substrate 210 may be distinguished from, for example, the “prepreg” or “FR4” core of a Printed Circuit Board (PCB) substrate which typically comprises glass fibers embedded in a resinous organic material, such as an epoxy.

The glass substrate 210 may have any suitable dimensions. In a particular embodiment, the glass substrate 210 may have a thickness that is approximately 50 μm or greater. For example, the thickness of the glass substrate 210 may be between approximately 50 μm and approximately 1.4 mm. Though, smaller or larger thicknesses may also be used. The glass substrate 210 may have edge dimensions (e.g., length, width, etc.) that are approximately 10 mm or greater. For example, edge dimensions may be between approximately 10 mm to approximately 250 mm. Though, larger or smaller edge dimensions may also be used. More generally, the area dimensions of the glass substrate 210 (from an overhead plan view) may be between approximately 10 mm×10 mm and approximately 250 mm×250 mm. In an embodiment, the glass substrate 210 may have a first side that is perpendicular or orthogonal to a second side. In a more general embodiment, the glass substrate 210 may comprise a rectangular prism volume with sections (e.g., vias) removed and filled with other materials (e.g., metal, etc.).

The glass substrate 210 may comprise a single monolithic layer of glass. In other embodiments, the glass substrate 210 may comprise two or more discrete layers of glass that are stacked over each other. The discrete layers of glass may be provided in direct contact with each other, or the discrete layers of glass may be mechanically coupled to each other by an adhesive or the like. The discrete layers of glass in the glass substrate 210 may each have a thickness less than approximately 50 μm. For example, discrete layers of glass in the glass substrate 210 may have thicknesses between approximately 25 μm and approximately 50 μm. Though, discrete layers of glass may have larger or smaller thicknesses in some embodiments. As used herein, “approximately” may refer to a range of values within ten percent of the stated value. For example approximately 50 μm may refer to a range between 45 μm and 55 μm.

The glass substrate 210 may be any suitable glass formulation that has the necessary mechanical robustness and compatibility with semiconductor packaging manufacturing and assembly processes. For example, the glass substrate 210 may comprise aluminosilicate glass, borosilicate glass, alumino-borosilicate glass, silica, fused silica, or the like. In some embodiments, the glass substrate 210 may include one or more additives, such as, but not limited to, Al₂O₃, B₂O₃, MgO, CaO, SrO, BaO, SnO₂, Na₂O, K₂O, SrO, P₂O₃, ZrO₂, Li₂O, Ti, or Zn. More generally, the glass substrate 210 may comprise silicon and oxygen, as well as any one or more of aluminum, boron, magnesium, calcium, barium, tin, sodium, potassium, strontium, phosphorus, zirconium, lithium, titanium, or zinc. In an embodiment, the glass substrate 210 may comprise at least 23 percent silicon (by weight) and at least 26 percent oxygen (by weight). In some embodiments, the glass substrate 210 may further comprise at least 5 percent aluminum (by weight).

In an embodiment, an opening 205 may be provided through a thickness of the glass substrate 210. The opening 205 may include sidewalls 211. The sidewalls 211 may include a tapered profile in some embodiments. That is, the sidewalls 211 may be non-orthogonal to the top and/or bottom surface of the glass substrate 210. In the particular embodiment shown in FIG. 2A, the opening 205 may have an hourglass shaped profile with the sidewalls 211 including a double taper. The profile of the sidewalls 211 may be defined at least in part by the patterning process used to form the opening 205 within the glass substrate 210. While tapered sidewalls 211 are shown in FIG. 2A, other embodiments may include substantially vertical sidewalls as well.

In an embodiment, the sidewalls 211 of the opening 205 may comprise an electrostatic charge. Particularly, the sidewalls 211 in FIG. 2A are positively charged 213. The charge along the sidewalls 211 may be provided by applying a conditioning agent to the glass substrate 210. For example, the conditioning agent may include a cationic conditioner to create the positively charged 213 sidewalls 211.

Referring now to FIG. 2B, a cross-sectional illustration of the portion of the package substrate 200 after colloids 214 are adsorbed onto the surfaces of the sidewalls 211 is shown, in accordance with an embodiment. The colloids 214 may be negatively charged colloids 214 in order to enable an electrostatic attraction between the colloids 214 and the positively charged 213 sidewalls 211. The colloids 214 may be applied with a wet process in order to provide full coverage along the thickness of the opening 205. For example, the wet process based on electrostatic interaction may enable a uniform coating over the sidewalls 211 for high aspect ratio openings. As used herein, high aspect ratio may refer to an aspect ratio (height:width) that is at least 3:1 or greater, least 5:1 or greater, at least 10:1 or greater, or at least 20:1 or greater.

In an embodiment, the colloids 214 may comprise a polymeric material and an electrically conductive carbon layer. Though, other conductive features may also be provided in the colloids 214 in different embodiments. The colloids 214 may be adsorbed onto the sidewalls 211 to provide a hybrid seed layer. As used herein, a hybrid seed layer may refer to a seed layer that comprises an electrically conductive portion and a polymeric portion. In an embodiment, binder molecules of the polymer in the colloids 214 may cross-link with the conditioning agent through thermal heating in an acidic condition to stabilize the hybrid seed layer. More generally, the cross-linked colloids may be oriented so that a layer of polymer material is electrostatically bonded to the sidewalls 211 and the carbon-based conductive material (e.g., graphite, graphene, etc.) is provided as a layer over the polymer material. That is, a carbon-based layer may be separated from the sidewalls by a polymer material in some embodiments. In some embodiments, the conductive carbon based material may include a first island of carbon that is coupled to the polymer and a second island of carbon that is coupled to the polymer. That is, the conductive carbon based material may include electrically isolated islands of carbon. Though, in other embodiments, the conductive carbon based material may form a substantially continuous layer, a continuous conductive network, and/or the like.

Referring now to FIG. 2C, a cross-sectional illustration of the portion of the package substrate 200 after a via 220 is plated over the hybrid seed layer 218 is shown, in accordance with an embodiment. In the illustrated embodiment, the hybrid seed layer 218 may be formed from the colloids 214 and is shown as a monolithic structure along the sidewalls 211 of the opening 205 for simplicity. In some instances, the hybrid seed layer 218 may have a thickness T that is up to approximately 50 nm, up to approximately 100 nm, up to approximately 500 nm, up to approximately 1.0 μm, or up to approximately 5.0 μm.

In an embodiment, the via 220 may be an electrically conductive material, such as copper or the like. The via 220 may be plated from the hybrid seed layer 218 with an electrochemical plating process. Due to the full coverage of the hybrid seed layer 218 along the sidewalls 211, the via 220 may have a fully filled structure even when the via 220 has a high aspect ratio. That is, the via 220 may be substantially void free or voidless. For example, the via 220 may have an aspect ratio (H:W) that is approximately 3:1 or greater, 5:1 or greater, or 10:1 or greater. In an embodiment, any excess copper may be removed from above the glass substrate 210 with a chemical mechanical polishing (CMP) process, or the like.

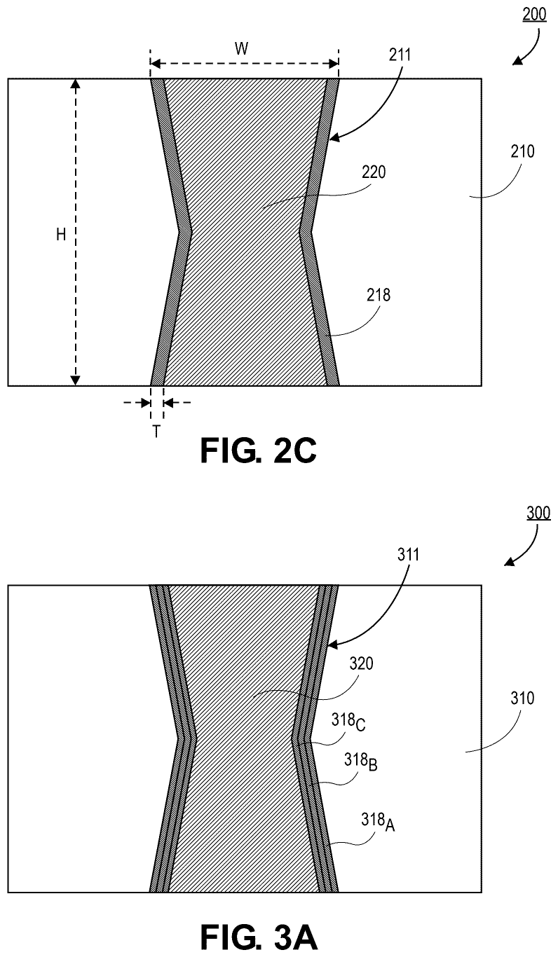

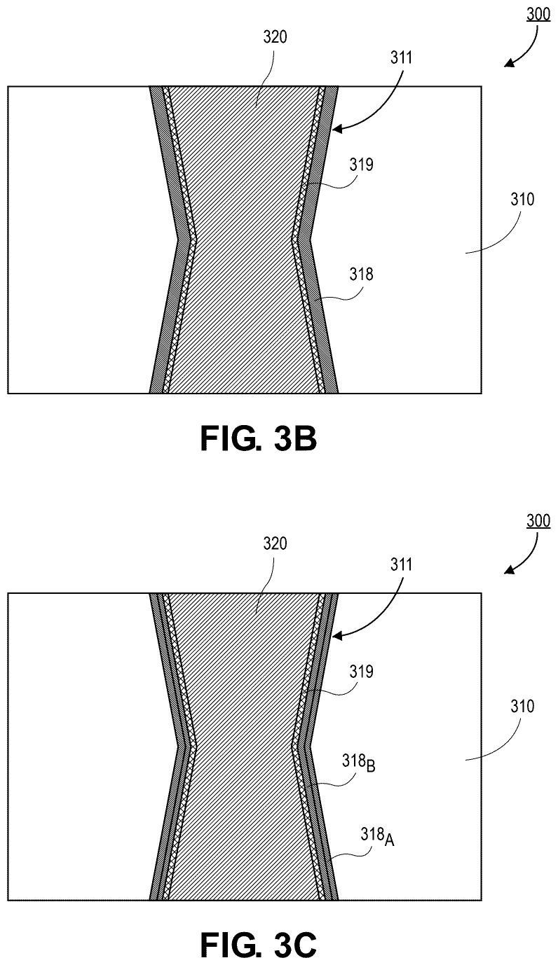

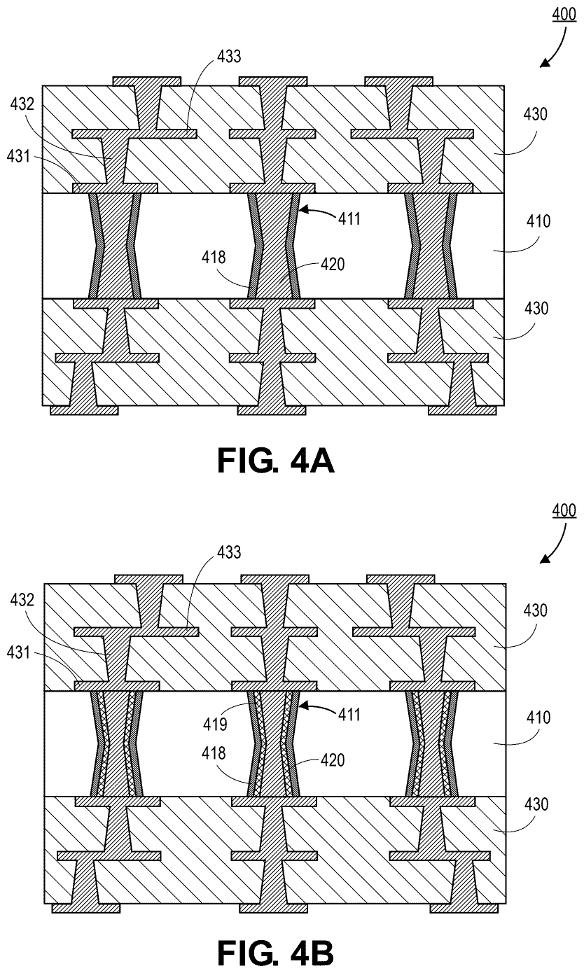

Referring now to FIGS. 3A-3C, a series of cross-sectional illustrations depicting portions of a package substrate 300 with different via 320 and hybrid seed layer 318 architectures is shown, in accordance with an embodiment.

Referring now to FIG. 3A, a cross-sectional illustration of a package substrate 300 is shown, in accordance with an embodiment. In an embodiment, the package substrate 300 may be similar to the package substrate 200 described herein, with the exception of the hybrid seed layer 318. Instead of a single hybrid seed layer 218, a plurality of hybrid seed layers 318 may be applied in a stack along the sidewall 311 of the glass substrate 310. For example, a stack of three hybrid seed layers 318_{A}, 318_{B}, and 318_{C} are shown in FIG. 3A. In some embodiments with multiple hybrid seed layers 318, each layer 318_{A}, 318_{B}, and 318_{C} may be referred to as sub-layers. The plurality of hybrid seed layers 318 may be formed by repeating the process shown in FIGS. 2A-2C a plurality of times. For example the stack of hybrid seed layers 318 may include alternating polymer and electrically conductive carbon-based layer layers. Providing multiple hybrid seed layers 318 may increase the amount of stress that can be absorbed by the hybrid seed layer 318. For example, the polymer portions of the stacked hybrid seed layer 318 may function as a mechanical buffer or liner that can be used to absorb stress within the glass substrate 310. As such, crack generation and propagation may be reduced compared to a purely metallic seed layer.

Referring now to FIG. 3B, a cross-sectional illustration of a package substrate 300 is shown, in accordance with an embodiment. In an embodiment, the package substrate 300 may be similar to the package substrate 300 in FIG. 3A, with the exception of the structure of the hybrid seed layer 318. Instead of a multi-layer hybrid seed layer 318 being in direct contact with the via 320, an electrically conductive liner 319 is provided between the hybrid seed layer 318 and the via 320. The liner may comprise copper or the like. For example, a liner 319 may be provided over the hybrid seed layer 318 to increase the conductivity of the sidewall 311. The presence of the electrically conductive liner 319 may improve the plating efficiency by improving the throwing power to enable more even plating. This further reduces the chances of forming voids in the via 320. In an embodiment, the liner 319 may be applied with a sputtering process or the like. Since the underlying hybrid seed layer 318 provides excellent coverage across the entire sidewall 311, the liner 319 does not need complete coverage through the entire thickness of the via opening in order to improve the plating process.

Referring now to FIG. 3C, a cross-sectional illustration of a package substrate 300 is shown, in accordance with an embodiment. In an embodiment, the package substrate 300 may be similar to the package substrate 300 in FIG. 3A, with the exception of the structure of the hybrid seed layers 318A-318B and liner 319. Instead of a multi-layer hybrid seed layers 318A-318B being in direct contact with the via 320, an electrically conductive liner 319 is provided between the multi-layer hybrid seed layers 318A-318B and the via 320. This combination of the embodiments of FIG. 3A and FIG. 3B allows for improved stress reduction (to reduce cracking the glass substrate 310) while also providing improved throwing power to improve plating uniformity.

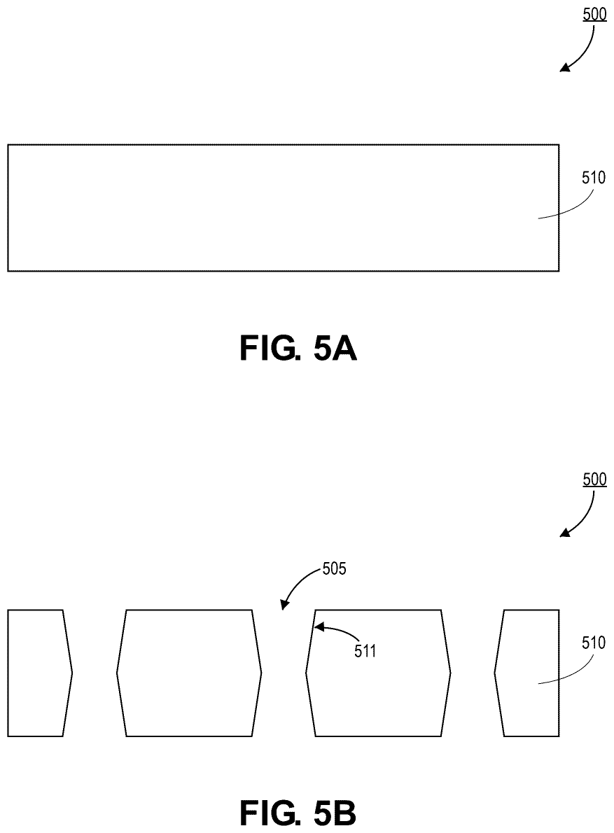

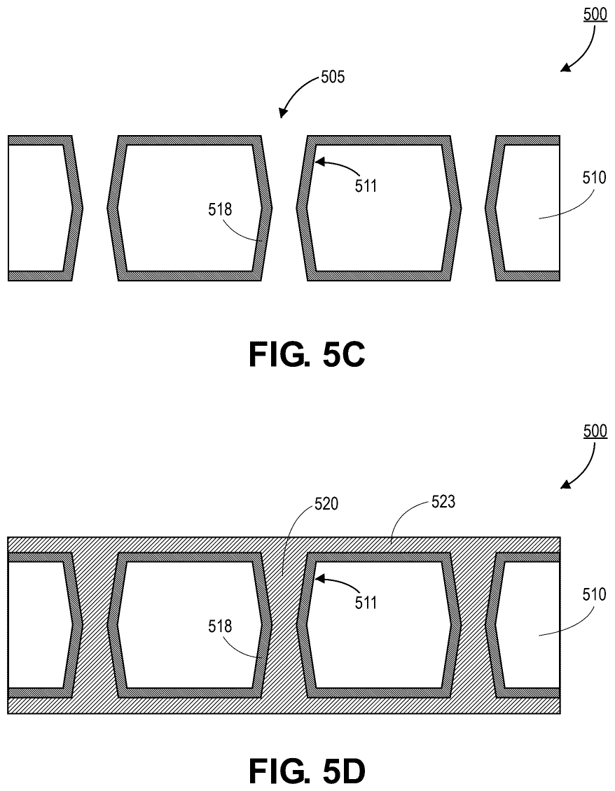

Referring now to FIGS. 4A and 4B, cross-sectional illustrations of package substrates 400 that include buildup layers 430 over and under the glass substrate 410 are shown, in accordance with an embodiment.

In FIG. 4A, the glass substrate 410 may comprise a hybrid seed layer 418 that lines a sidewall 411 of the glass substrate 410. The hybrid seed layer 418 may be similar to any of the hybrid seed layers described in greater detail herein. For example, the hybrid seed layer 418 may comprise a polymeric material and an electrically conductive carbon-based material. The via 420 may be plated up from the hybrid seed layer 418. In an embodiment, the buildup layers 430 over and/or under the glass substrate 410 may comprise organic dielectric material, such as buildup film or the like. Pads 431, vias 432, and traces 433 may be fabricated within the buildup layers 430 using standard package assembly processes.

In FIG. 4B, the package substrate 400 may be similar to the package substrate 400 in FIG. 4A, with the addition of a liner 419 between the hybrid seed layer 418 and the via 420. The liner 419 may be an electrically conductive material, such as a copper liner 419. The liner 419 may be applied with a sputtering process or the like in order to provide a more electrically conductive surface for plating the via 420. As such, the throwing power is increased and the plating uniformity is improved. This can lead to an even further reduction in the chance of void formation in the via 420.

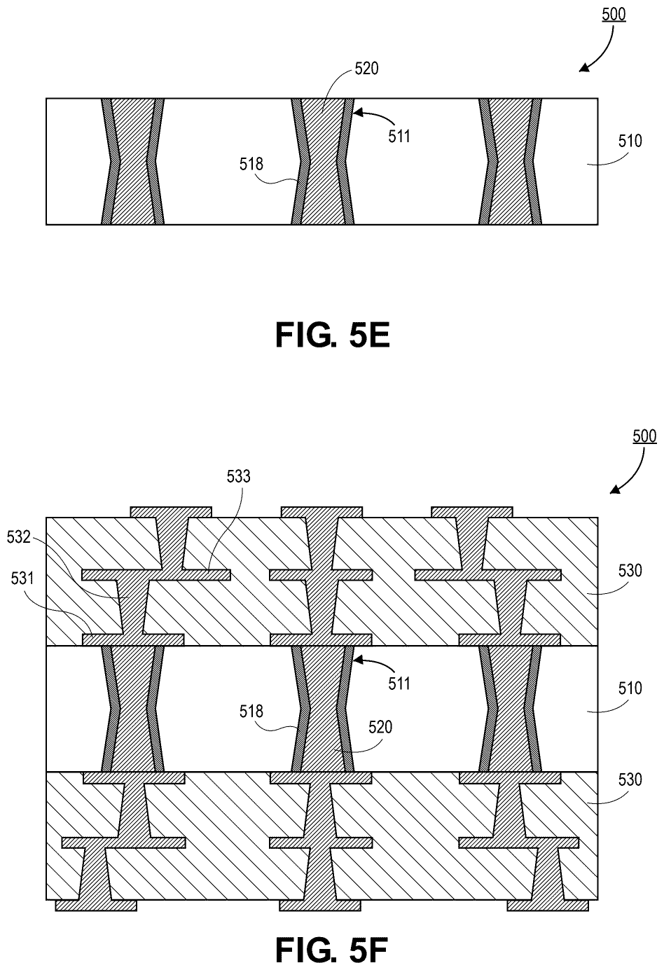

Referring now to FIGS. 5A-5F, a series of cross-sectional illustrations depicting a process for forming a package substrate with a glass substrate 510 for a core and high aspect ratio vias 520 that are plated from a hybrid seed layer 518 is shown, in accordance with an embodiment.

Referring now to FIG. 5A, a cross-sectional illustration of a portion of a package substrate 500 at a stage of manufacture is shown, in accordance with an embodiment. In an embodiment, the package substrate 500 may comprise a glass substrate 510. The glass substrate 510 may be similar to any of the glass substrates described in greater detail herein.

Referring now to FIG. 5B, a cross-sectional illustration of the portion of the package substrate 500 at an additional stage of manufacture is shown, in accordance with an embodiment. In an embodiment, the package substrate 500 may have a plurality of via openings 505 formed through a thickness of the glass substrate 510. The via openings 505 may be formed with any suitable process. For example, the via openings 505 may be formed with a laser assisted etching process. A laser assisted etching process may include exposing portions of the glass substrate 510 with a laser to modify a structure of the glass substrate 510 and etching the modified regions with an etching chemistry. In an embodiment, sidewalls 511 of the via openings 505 may include any suitable profile. For example, the sidewalls 511 in FIG. 5B include an hourglass shaped profile. Though, other embodiments may include sidewalls 511 that include vertical profiles, or a profile with a single taper. In an embodiment, the via openings 505 may be high aspect ratio via openings 505. For example, a hieght:width ratio of the via openings 505 may be approximately 3:1 or greater, approximately 5:1 or greater, or approximately 10:1 or greater.

Referring now to FIG. 5C, a cross-sectional illustration of the portion of the package substrate 500 after a hybrid seed layer 518 is applied to surfaces of the glass substrate 510, including the sidewalls 511 of the via openings 505 is shown, in accordance with an embodiment. In an embodiment, the hybrid seed layer 518 may comprise a polymeric material with an overlying electrically conductive material. For example, the electrically conductive material may comprise a carbon-based material, such as graphite, graphene, or the like. In an embodiment, the hybrid seed layer 518 may be applied with processes similar to any of the processes for forming hybrid seed layers described in greater detail herein, such as through the use of electrostatic attraction.

For example, the surfaces of the glass substrate 510 may be charged (e.g., positively charged), and colloids that comprise a polymer and a carbon (e.g., graphite, graphene, etc.) are negatively charged. As such, the negatively charged colloids are attracted to the surface of the glass substrate 510. The electrostatic attraction also enables uniform deposition without the need for the mechanical shocking or agitation that may result in damage to the glass core. In an embodiment, the hybrid seed layer 518 may be stabilized by cross-linking polymeric portions of the colloid and a conditioner on the surface of the glass core. As shown, the hybrid seed layer 518 may be deposited on the sidewalls 511 of the via openings 505 and over the top and bottom surfaces of the glass substrate 510.

In the embodiment shown in FIG. 5C, a single layer of the hybrid seed layer 518 is shown as one example. Though, other embodiments may include a plurality of stacked hybrid seed layers 518 that are deposited sequentially, similar to the embodiment shown in FIG. 3A. Other embodiments may also include depositing an electrically conductive liner over the hybrid seed layer 518 in order to improve the throwing power, similar to the embodiment shown in FIG. 3B. Such a liner may be deposited with a sputtering process or the like.

Referring now to FIG. 5D, a cross-sectional illustration of the portion of the package substrate 500 after vias 520 are plated is shown, in accordance with an embodiment. In an embodiment, the vias 520 may be plated up from the hybrid seed layer 518 (and/or from an electrically conductive liner over the hybrid seed layer 518) using an electrochemical plating process. In an embodiment, the plating process may also result in overburden 523 being plated over the top and bottom surfaces of the glass substrate 510.

Referring now to FIG. 5E, a cross-sectional illustration of the portion of the package substrate 500 after a polishing process is shown, in accordance with an embodiment. As shown, the overburden 523 and portions of the hybrid seed layer 518 over the top and bottom surfaces of the glass substrate 510 may be removed. The overburden 523 and the portions of the hybrid seed layer 518 may be removed with a CMP process, an etching process, or the like.

Referring now to FIG. 5F, a cross-sectional illustration of the portion of the package substrate 500 after buildup layers 530 are formed over and under the glass substrate 510 is shown, in accordance with an embodiment. In an embodiment, the buildup layers 530 may comprise organic dielectric material, such as buildup film or the like. Pads 531, vias 532, traces 533, and the like may be formed within the buildup layers 530 using typical patterning and deposition processes for electronic package fabrication processes.

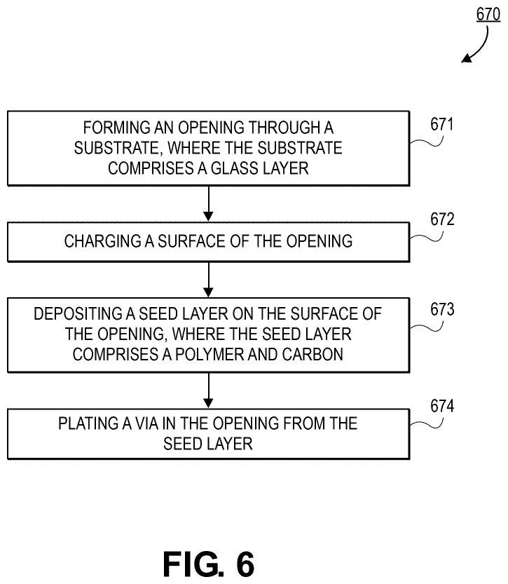

Referring now to FIG. 6, a flow diagram of a process 670 for forming a package substrate with high aspect ratio vias and a hybrid seed layer is shown, in accordance with an embodiment. In an embodiment, the process 670 may begin with operation 671, which comprises forming an opening through a substrate. In an embodiment, the substrate comprises a glass layer, such as any of the glass substrates described in greater detail herein. In an embodiment, the opening may be formed with a laser assisted etching process or any other subtractive process. In an embodiment, the opening is a high aspect ratio opening with a height: width ratio that is approximately 3:1 or greater, approximately 5:1 or greater, or approximately 10:1 or greater.

In an embodiment, the process 670 may continue with operation 672, which comprises charging a surface of the opening. In an embodiment, the surface of the opening may be charged by applying a conditioning agent to the substrate. For example, the conditioning agent may include a cationic conditioner to create the positively charged sidewalls.

In an embodiment, the process 670 may continue with operation 673, which comprises depositing a seed layer on the surface of the opening. In an embodiment, the seed layer comprises a polymer and carbon. In an embodiment, the polymer may be attracted to the charged sidewalls through electrostatic attraction. The carbon may comprise graphite, graphene, or the like in order to provide an electrically conductive surface over the polymer. More generally, colloids that comprise a polymer and a carbon (e.g., graphite, graphene, etc.) are negatively charged and attracted to the surface of the glass substrate. The electrostatic attraction also enables uniform deposition in the high aspect ratio opening without the need for the mechanical shocking or agitation that may result in damage to the glass substrate. In an embodiment, the seed layer may be stabilized by cross-linking polymeric portions of the colloid and a conditioner on the sidewall of the glass substrate.

In some embodiments, a single layer of the seed layer is applied over the sidewall of the opening. In other embodiments, the seed layer deposition process is repeated a plurality of times in order to provide a multi-layer stack of seed layers. Embodiments may also comprise applying a liner over the seed layer to improve throwing power. For example, a copper liner may be deposited over at least some portions of the seed layer with a sputtering process or the like.

In an embodiment, the process 670 may continue with operation 674, which comprises plating a via in the opening from the seed layer. In an embodiment, the via may be plated from the seed layer with an electrochemical plating process or the like. Any overburden may be removed (e.g., with a CMP process or the like). After the via is formed, buildup layers and electrical routing may be formed over and/or under the glass substrate.

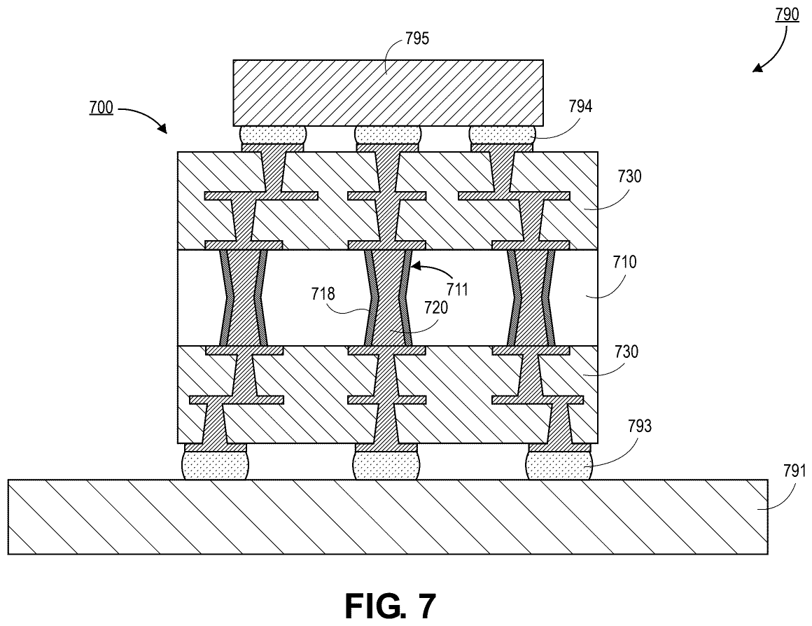

Referring now to FIG. 7, a cross-sectional illustration of an electronic system 790 is shown, in accordance with an embodiment. In an embodiment, the electronic system 790 may comprise a board 791, such as a printed circuit board (PCB), a motherboard, or the like. In an embodiment, the board 791 may be electrically coupled to a package substrate 700 by interconnects 793. The interconnects 793 may comprise solder balls, sockets, pins, or any other suitable second level interconnect (SLI) architecture.

In an embodiment, the package substrate 700 may be similar to any of the package substrates described in greater detail herein. For example, the package substrate 700 may comprise a glass substrate 710 for the core with buildup layers 730 over and/or under the glass substrate 710. In an embodiment, high aspect ratio vias 720 may be formed through a thickness of the glass substrate 710. The vias 720 may be plated up from a hybrid seed layer 718 that is formed along sidewalls 711 of the glass substrate 710. That is, the hybrid seed layer 718 may surround a perimeter of the via 720. In an embodiment, the hybrid seed layer 718 may be similar to any of the hybrid seed layers described in greater detail herein. For example, the hybrid seed layer 718 may comprise a polymer and an electrically conductive carbon-based layer (e.g., graphite, graphene, or the like). Further, while shown as a single layer, it is to be appreciated that multiple hybrid seed layers 718 may be used and/or an electrically conductive liner (e.g., a copper liner) may be deposited over at least a portion of the hybrid seed layer 718 in other embodiments.

In an embodiment, one or more dies 795 may be electrically coupled to the package substrate 700 through interconnects 794. In an embodiment, the interconnects 794 may comprise solder balls, copper bumps, hybrid bonding interfaces, or any other suitable first level interconnect (FLI) architecture. In an embodiment, the one or more dies 795 may comprise any type of die, such as processor (e.g., a central processing unit (CPU), a graphics processing unit (GPU), an XPU, etc.), a memory die, a communications die, and/or the like.

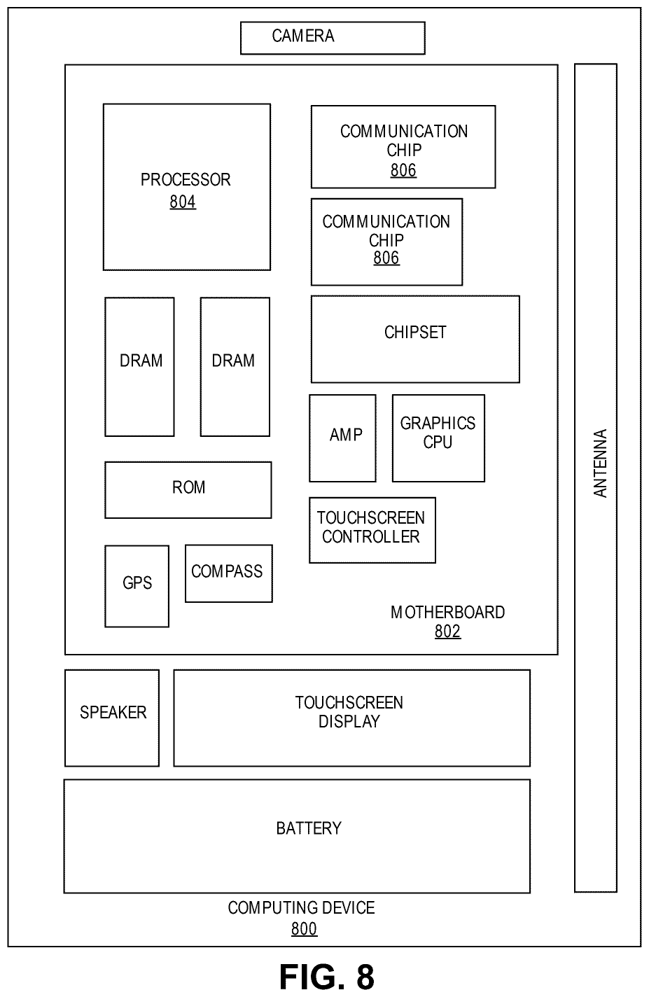

FIG. 8 illustrates a computing device 800 in accordance with one implementation of the disclosure. The computing device 800 houses a board 802. The board 802 may include a number of components, including but not limited to a processor 804 and at least one communication chip 806. The processor 804 is physically and electrically coupled to the board 802. In some implementations the at least one communication chip 806 is also physically and electrically coupled to the board 802. In further implementations, the communication chip 806 is part of the processor 804.

These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 806 enables wireless communications for the transfer of data to and from the computing device 800. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 806 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 800 may include a plurality of communication chips 806. For instance, a first communication chip 806 may be dedicated to shorter range wireless communications such as Wi-Fi and Bluetooth and a second communication chip 806 may be dedicated to longer range wireless communications such as GPS, EDGE, GPRS, CDMA, WiMAX, LTE, Ev-DO, and others.

The processor 804 of the computing device 800 includes an integrated circuit die packaged within the processor 804. In some implementations of the disclosure, the integrated circuit die of the processor may be part of an electronic package that comprises a glass substrate core with a via that is plated from a seed layer that comprises a polymer and carbon, in accordance with embodiments described herein. The term “processor” may refer to any device or portion of a device that processes electronic data from registers and/or memory to transform that electronic data into other electronic data that may be stored in registers and/or memory.

The communication chip 806 also includes an integrated circuit die packaged within the communication chip 806. In accordance with another implementation of the disclosure, the integrated circuit die of the communication chip may be part of an electronic package that comprises a glass substrate core with a via that is plated from a seed layer that comprises a polymer and carbon, in accordance with embodiments described herein.

In an embodiment, the computing device 800 may be part of any apparatus. For example, the computing device may be part of a personal computer, a server, a mobile device, a tablet, an automobile, or the like. That is, the computing device 800 is not limited to being used for any particular type of system, and the computing device 800 may be included in any apparatus that may benefit from computing functionality.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize.

These modifications may be made to the disclosure in light of the above detailed description. The terms used in the following claims should not be construed to limit the disclosure to the specific implementations disclosed in the specification and the claims. Rather, the scope of the disclosure is to be determined entirely by the following claims, which are to be construed in accordance with established doctrines of claim interpretation.

Example 1: an apparatus, comprising: a substrate, wherein the substrate comprises glass; an opening through a thickness of the substrate; a layer along a sidewall of the opening, wherein the layer comprises a polymer and an electrical conductor that comprises carbon; and a via in the opening, wherein the via is an electrically conductive material.

Example 2: the apparatus of Example 1, wherein the electrical conductor comprises graphite or graphene.

Example 3: the apparatus of Example 1 or Example 2, wherein the layer has a thickness up to approximately 5.0 μm.

Example 4: the apparatus of Examples 1-3, wherein the opening has an aspect ratio (height: width) that is approximately 10:1 or greater.

Example 5: the apparatus of Examples 1-4, wherein the opening has an hourglass shaped cross-section.

Example 6: the apparatus of Examples 1-5, wherein the layer comprises a plurality of sub-layers.

Example 7: the apparatus of Examples 1-6, further comprising: a copper layer between the layer and the via.

Example 8: the apparatus of Examples 1-7, wherein the layer comprises cross-linked colloids comprising the polymer and the electrical conductor.

Example 9: the apparatus of Examples 1-8, wherein the carbon of the electrical conductor comprises a first island of carbon coupled to the polymer and a second island of carbon coupled to the polymer, wherein the first island of carbon is electrically isolated from the second island of carbon.

Example 10: the apparatus of Examples 1-9, wherein the layer and the via fully fill the opening.

Example 11: an apparatus, comprising: a core, wherein the core comprises a glass layer; a via through a thickness of the core; a seed layer between the via and the core, wherein the seed layer comprises a colloid that comprises a polymer and an electrically conductive carbon-based material; and a first buildup layer over the core and a second buildup layer under the core, wherein the first buildup layer and the second buildup layer comprise an organic dielectric material.

Example 12: the apparatus of Example 11, wherein the via has an aspect ratio (height: width) that is 10:1 or greater.

Example 13: the apparatus of Example 11 or Example 12, wherein the via has tapered sidewalls.

Example 14: the apparatus of Examples 11-13, wherein the seed layer has a thickness of 5.0 μm or less.

Example 15: the apparatus of Examples 11-14, wherein the seed layer is adsorbed to the core through an electrostatic attraction between the core and the seed layer.

Example 16: the apparatus of Examples 11-15, further comprising: a die coupled to the first buildup layer; and a board coupled to the second buildup layer.

Example 17: an apparatus, comprising: a package substrate with a glass core between organic buildup layers; a via through the glass core; and a hybrid seed layer between the via and the glass core, wherein the hybrid seed layer comprises an organic polymer contacting the glass core and a layer comprising carbon over the organic polymer.

Example 18: the apparatus of Example 17, wherein the hybrid seed layer surrounds a perimeter of the via.

Example 19: the apparatus of Example 17 or Example 18, wherein the via is voidless.

Example 20: the apparatus of Examples 17-19, wherein the hybrid seed layer is adsorbed to the glass core by an electrostatic attraction.

What is claimed is:

1. An apparatus, comprising:
a substrate, wherein the substrate comprises glass;
an opening through a thickness of the substrate;
a layer along a sidewall of the opening, wherein the layer comprises a polymer and an electrical conductor that comprises carbon; and
a via in the opening, wherein the via is an electrically conductive material.

2. The apparatus of claim 1, wherein the electrical conductor comprises graphite or graphene.

3. The apparatus of claim 1, wherein the layer has a thickness up to approximately 5.0 μm.

4. The apparatus of claim 1, wherein the opening has an aspect ratio (height: width) that is approximately 10:1 or greater.

5. The apparatus of claim 1, wherein the opening has an hourglass shaped cross-section.

6. The apparatus of claim 1, wherein the layer comprises a plurality of sub-layers.

7. The apparatus of claim 1, further comprising:
a copper layer between the layer and the via.

8. The apparatus of claim 1, wherein the layer comprises cross-linked colloids comprising the polymer and the electrical conductor.

9. The apparatus of claim 1, wherein the carbon of the electrical conductor comprises a first island of carbon coupled to the polymer and a second island of carbon coupled to the polymer, wherein the first island of carbon is electrically isolated from the second island of carbon.

10. The apparatus of claim 1, wherein the layer and the via fully fill the opening.

11. An apparatus, comprising:
a core, wherein the core comprises a glass layer;
a via through a thickness of the core;
a seed layer between the via and the core, wherein the seed layer comprises a colloid that comprises a polymer and an electrically conductive carbon-based material; and
a first buildup layer over the core and a second buildup layer under the core, wherein the first buildup layer and the second buildup layer comprise an organic dielectric material.

12. The apparatus of claim 11, wherein the via has an aspect ratio (height:width) that is 10:1 or greater.

13. The apparatus of claim 11, wherein the via has tapered sidewalls.

14. The apparatus of claim 11, wherein the seed layer has a thickness of 5.0 μm or less.

15. The apparatus of claim 11, wherein the seed layer is adsorbed to the core through an electrostatic attraction between the core and the seed layer.

16. The apparatus of claim 11, further comprising:
a die coupled to the first buildup layer; and
a board coupled to the second buildup layer.

17. An apparatus, comprising:
a package substrate with a glass core between organic buildup layers;
a via through the glass core; and
a hybrid seed layer between the via and the glass core, wherein the hybrid seed layer comprises an organic polymer contacting the glass core and a layer comprising carbon over the organic polymer.

18. The apparatus of claim 17, wherein the hybrid seed layer surrounds a perimeter of the via.

19. The apparatus of claim 17, wherein the via is voidless.

20. The apparatus of claim 17, wherein the hybrid seed layer is adsorbed to the glass core by an electrostatic attraction.
